(19) United States
(12) Patent Application Publication
(10) Pub. No.: US 2009/0057137 A1
(43) Pub. Date: Mar. 5, 2009

(54) SYNTHESIZING THIN FILMS OF LITHIATED TRANSITION METAL OXIDE FOR USE IN ELECTROCHEMICAL AND BATTERY DEVICES

(75) Inventors: J. Roland Pitts, Lakewood, CO (US); Se-Hee Lee, Louisville, CO (US); C. Edwin Tracy, Golden, CO (US); Dane Gillaspie, Golden, CO (US)

Correspondence Address: PAUL J WHITE, PATENT COUNSEL;NATIONAL RENEWABLE ENERGY LABORATORY (NREL), 1617 COLE BOULEVARD, MS 1734, GOLDEN, CO, 80401-3393, US

(73) Assignee: Midwest Research Institute, Kansas City, MO (US)

(21) Appl. No.: 12/194,741

(22) Filed: Aug. 20, 2008

Related U.S. Application Data
(63) Continuation-in-part of application No. PCT/US07/77419, filed on Aug. 31, 2007.

(51) Int. Cl. B05D 5/12; C23C 14/34

(52) U.S. Cl. 204/192.15; 427/77

(57) ABSTRACT

A method (100) is provided for synthesizing a thin film electrode (350) such as an electrochromic (EC) electrode (426) or counter electrode (434) for an EC device (410), a lithiated film of transition metal oxide (616) for a battery device (600), or the like. The method (100) includes providing (140) a source material (322) within a deposition chamber (310) such as a target for sputtering, and the source material (322) includes a transition metal oxide and ionic lithium. The method (100) continues with positioning (140) an electrically conductive substrate (340) with an exposed surface within the deposition chamber (310). A thin film (350) of the transition metal oxide and the ionic lithium is deposited upon the exposed surface of the substrate (340) using physical vapor deposition with the source material (322) to form in a single deposition step a layer of lithiated transition metal oxide (350).

### CROSS-REFERENCE TO RELATED APPLICATIONS

This application is a continuation-in-part of PCT Application No. PCT/U.S.07/77419, filed on Aug. 31, 2007, which is incorporated herein by reference in its entirety.

### CONTRACTUAL ORIGIN

The United States Government has rights in this invention under Contract No. DE-AC36-99GO10337 between the United States Department of Energy and the National Renewable Energy Laboratory, a Division of the Midwest Research Institute.

### BACKGROUND

In recent years, there has been significant interest in electrochemical materials for a variety of applications such as smart windows to increase energy efficiency, switchable mirrors for automobiles, transparent displays, and a variety of other applications. Electrochromic materials are useful electrochemical materials that can change their optical properties upon charge insertion and extraction. Electrochromic materials are being widely developed and used for building and automotive windows as a small amount of voltage can be applied to modify the transmission of light (e.g., to block sunlight to reduce the need for air conditioning or to reduce glare). Specifically, when thin films of electrochromic materials are integrated into devices such as windows, it becomes possible to modulate transmittance, reflectance, absortance, and emittance of light.

Common electrochromic devices have five layers on one substrate or positioned between two substrates, with the substrates being a transparent glass, polyester foil or the like. The central part of the five-layer construction is an ion conductor (e.g., an electrolyte) that may be inorganic such as an oxide film or organic such as an adhesive polymer, with small ions such as lithium ions (Li⁺) being preferred in many cases in part due their small size that enhances their mobility. On one side of the ion conductor is an electrochromic layer (e.g., a thin film of tungsten oxide or the like that may be thought of as the electrochromic (EC) electrode) that is capable of conducting electrons as well as ions (e.g., lithium ions). On the other side of the ion conductor, another layer or thin film is provided that serves to store ions (e.g., lithium ions), and this thin film or layer may be considered a counter electrode that typically has electrochromic properties that are complementary to those of the EC electrode. It is understood that this structure for an EC device is equivalent to a lithium battery. This central three-layer structure is positioned between a pair of transparent conductors, with In₂O₃:Sn (or ITO) being a commonly used transparent thin film conductor for EC devices. When a voltage on the order of one to three volts is applied between the transparent conductors, ions are moved between the counter electrode and the EC electrode to alter the optical properties of the EC device.

Fabricating smart windows and other EC devices has presented a number of challenges that have increased manufacturing costs and otherwise slowed adoption of some EC devices. For example, a conventional Li-based, all-solid-state EC device may be composed of a thin film layered stack, as discussed above, including a transparent conducting oxide (TCO) electrode, a cathodic EC layer, an ion conductor, an anodic EC layer, and a TCO electrode. During fabrication of these types of EC devices, the two EC layers may be applied or deposited on the previously applied layer without lithium and then a later or post-deposition step is required to insert or provide the mobile lithium ions.

Specifically, either (or both) of the EC layers usually require lithiation in a separate and subsequent procedure such as diffusion or deposition of lithium in a post-deposition step or an electrochemical method may be used to provide the lithium ions needed for proper EC device operation. Some deposition processes for fabricating the counter electrode have used compounds including lithium, but the lithium has not been deposited in a mobile, ionic form. Instead, conventional fabrication techniques for Li-based EC devices or EC thin films have called for first forming an electrochromic thin film without lithium in mobile form, and then performing a costly and often complex or problematic second or later step of inserting, intercalating, and/or diffusing of lithium into the electrochromic film (which may be a transition metal oxide film). The later step is required to produce a useful EC device as it provides the metal oxide (e.g., the EC electrode or counter electrode) with mobile monovalent lithium ions that participate in the intercalation/deintercalation processes necessary for thin film electrochromic or battery device operations.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

This is achieved, in part, by providing a synthesis method for forming a thin layer of lithiated transition metal oxide that may be used in fabricating electrochromic or battery electrodes (e.g., to form electrochemical devices such as EC devices and thin film batteries). The method may include forming (or otherwise providing) lithiated target materials such as deposition targets with lithium in or readily moved to ionic form. The method may then include using the lithiated target materials in a synthesis process, such as a target for a physical vapor deposition (PVD) process, to directly deposit a lithiated EC transition metal oxide thin film on a substrate, which may be used as or further processed to form an EC or battery electrode. As will be appreciated, the thin film or electrode fabrication process provides a more cost effective and less complex manufacturing process that is capable of producing novel and/or advantageous thin-film properties in transition metal oxide materials.

More particularly, a method is provided for synthesizing a thin film electrode, e.g., a EC electrode or counter electrode for an EC device, a lithiated film of transition metal oxide for a battery device, or the like. The method includes providing a source material within a deposition chamber (e.g., a target for a sputtering device), and, in some embodiments, the source material includes a transition metal oxide and lithium. The method continues with positioning an electrically conductive substrate with an exposed surface within the deposition chamber. A thin film of the transition metal oxide and the lithium is then deposited upon the exposed surface of the substrate using physical vapor deposition with the source material. The lithium in the thin film is in ionic form and is mobile to allow the thin film to function as an electrode (e.g., an EC electrode of an EC device or the like). The lithium in the target or source material may be in ionic form and be of such concentration that the deposited film has adequate amounts of mobile lithium ions to act as an electrode. The transition metal oxide may be nearly any transition metal with tungsten being one useful example, and the source material may include one or more additives to provide a desired functionality such as an active metal such as nickel. The surface of the substrate may include a transparent conducting oxide such as when the thin film will be used in fabricating an EC device, and in some embodiments, the method may include forming a target with the source material prior to PVD processes including adding heat or other processing to place the lithium in ionic form (or to increase the concentration or quantity of mobile lithium ions in the target).

According to another aspect or embodiment, a method is provided for fabricating an EC device that includes providing a substrate including a transparent conductor layer. The method then includes performing PVD upon the transparent conductor layer using a target made from lithiated EC material. For example, the lithiated EC material may include a transition metal oxide (e.g., tungsten oxide or the like) and the PVD may generate a thin film of the transition metal oxide with mobile lithium ions. The method may include forming a target for the PVD process from a source of lithium in ionic form and a transition metal oxide material, and/or such forming may include processing (e.g., heating, applying pressure, or the like) the lithium source material to produce a desired amount of the ionic lithium in the target. The method may further include providing (or depositing) an ion conductor on the thin film formed in the first PVD step (e.g., upon an EC electrode on the TCO layer) and then performing a second PVD step using a second target of lithiated EC material to produce a thin film on the ion conductor. For example, the thin film may be formed from this second target of differing materials to form complementary acting material to the EC electrode material, thereby producing a counter electrode on the ion conductor.

In addition to the exemplary aspects and embodiments described above, further aspects and embodiments will become apparent by reference to the drawings and by study of the following descriptions.

### BRIEF DESCRIPTION OF THE DETAILED DRAWINGS

Exemplary embodiments are illustrated in referenced figures of the drawings. It is intended that the embodiments and figures disclosed herein are to be considered illustrative rather than limiting.

FIG. 1 is a flow chart of an exemplary method for fabricating an electrochemical thin film device including the synthesis of a lithiated transition metal oxide;

FIG. 2 illustrates in schematic or functional block form the formation of a physical vapor deposition target for use in synthesis of a lithiated transition metal oxide (e.g., an EC thin film or the like) with the target including lithium in ionic form;

FIG. 3 illustrates in block form a thin film synthesis or deposition assembly for use in forming electrochemical thin films by depositing a lithiated transition metal oxide onto a substrate;

FIG. 4 is a schematic view of an electrochromic device (such as a smart window, a switchable mirror, or the like) fabricated with at least one electrochemical thin film according an embodiment described herein such as a lithiated transition metal oxide deposited with the system of FIG. 3 and/or the process of FIG. 1;

FIG. 5 is a diagrammatic section view of an electrochromic device that includes a positive or counter electrode; and

FIG. 6 is a diagrammatic section view of a lithium-based thin film battery device.

### DESCRIPTION

The following provides a description of exemplary fabrication/synthesis methods for forming electrochemical thin films and of devices such as electrochromic (EC) devices and thin film batteries that may include such thin films. As discussed above, conventional Li-based EC devices and thin film batteries are fabricated with a pair of electrodes typically formed by first depositing a thin film of a transition metal oxide and then a second step (such as a lithiation step) is performed to provide the metal oxide with mobile monovalent lithium ions. These mobile ions provide the charge storage mechanism which enables desired solid state thin film electrochromic and/or battery functions. The methods described herein eliminate the need for a post-lithiation process as it teaches fabrication of a lithiated electrochemical metal oxide thin film in a single deposition or synthesis step.

The thin film (e.g., electrode) fabrication method avoids the additional, costly, and troublesome post-deposition lithiation step. The method involves forming (or providing) an inherent EC material as a source (e.g., a target) for thin film synthesis, which may include physical vapor deposition using an EC material target and may be used in forming one or both the cathodic and anodic intercalation layers of EC devices and thin film batteries (e.g., the counter electrode and the EC electrode). By using such a lithiated EC material as a source material, a lithiated thin film layer containing a significant amount of lithium can be deposited without a post-deposition lithium process. In other words, a target formed according to present method facilitates a one-step synthesis technique for directly and instantaneously creating lithiated EC transition metal oxide. Significantly, the lithium in the formed (e.g., deposited) thin film is deposited in unbound, unreacted mobile ionic form and is available, in useful quantities, for intercalation to and from an adjacent electrolyte or ion conductor layer.

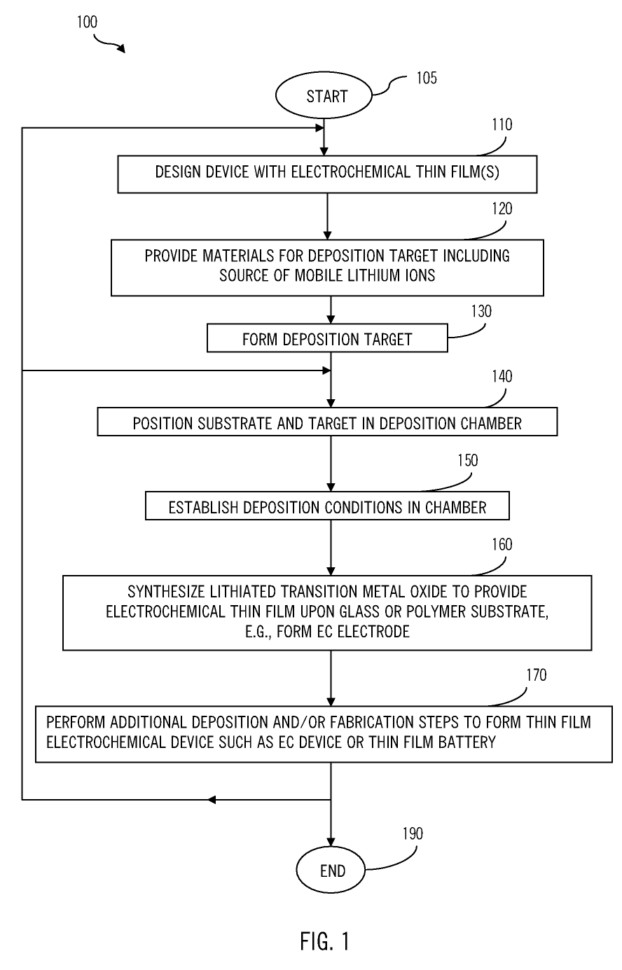

FIG. 1 illustrates a fabrication or manufacturing method 100 that may be used to synthesize or form thin film of lithiated transition metal oxide materials (such as may be used as electrodes) and to form EC devices and thin film batteries. The method 100 starts at 105 such as with a decision of a type of electrochemical device to form with the method. At 110 the method 100 continues more specifically with designing a device with one or more electrochemical thin films. For example, step 110 may include making a decision to form a particular EC device such as a “smart window” (e.g., a window with an EC coating that can electronically control the flow of solar light in heat in response to changing outdoor conditions or an applied charge) or a “switchable mirror” (e.g., glass or other material panel with a coating capable of switching back and forth between a transparent state and a reflective one) and then choosing materials (and thickness ranges) for the first and optional second substrates (or other layers that are typically glass or plastic), for the transparent conductors, for the counter electrode and the EC electrode thin films or layers, and for the central electrolyte or ion conductor. If at step 110 a battery device was selected, the outer substrate may be eliminated in the design of the device, the transparent conductors may be replaced with non-transparent conductor materials, and the counter electrode, the EC electrode, and the ion conductor may use differing materials as transparency would not be important for a battery.

At step 120, based on the device that was designed in step 110, the method 100 may continue with providing materials for use as source material (e.g., a deposition target) in the synthesis of the lithiated transition metal oxide layer/thin film or, in many cases, the formation of the counter and EC electrodes. Significantly, step 120 includes choosing at least one source of lithium and, more preferably, of mobile lithium ions for the deposition source material (e.g., not a source of lithium that would produce a deposition target with bound or unavailable lithium that would, in turn, produce a thin film with bound lithium or a deficiency in lithium ions). Additionally, the source materials will generally include one or more materials to provide desired transition metals such as tungsten, molybdenum, vanadium, nickel, iron, and the like. At step 130, if necessary for the type of deposition used, the source materials selected and provided at step 120 are formed into a deposition target (or synthesis source).

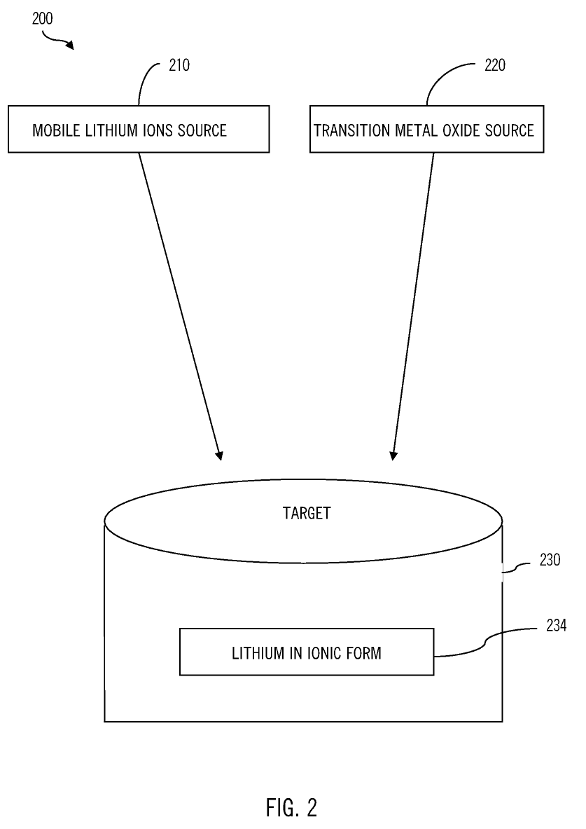

FIG. 2 illustrates with functional block diagram 200 the processes of steps 120, 130 of FIG. 1. As shown, a source material for mobile lithium ions 210 is provided, which along with a transition metal oxide source 220 are selected and provided and then processed to form a target 230 with a quantity of lithium in ionic form 234. In other words, the lithium ion source 210 is selected such that when the target 230 is formed it may be considered a lithiated EC material in which the lithium 234 is in ionic form such that it will be unbound and mobile when deposited and in high enough concentrations or quantities in the target 230 such that when the target 230 is used in synthesis of a thin film of transition metal oxide the metal oxide is also lithiated. In some cases, the lithium ions source 210 may take the form of Li₂O or LiCO₃ such as in powder form. The transition metal oxide source 220 may take a number of forms to practice the invention with tungsten often being included in EC thin films or electrodes. Hence, the source 220 may include WO₃ or the like in powder or other form to provide tungsten to the target 230 and additional additives such as active metals like nickel may be provided by including NiO or the like in powder or other form. Other oxides, of course may be electrochromic or find use in thin film devices and the source 220 may include any of these such as Nb₂O₅, NiO, MoO₃, Ir₂O₃, V₂O₅, and the like.

A target may be formed into a wafer, a pellet, or other form to facilitate later use in deposition by mixing and application of pressure and additional processing may be used such as firing or applying heat such as to create a ceramic target and, in some cases, to provide sufficient quantities of ionic lithium and burn off carbon. In place of pellets or ceramic targets, the target 230 may take other forms such as a metal rod (e.g., a LiNi alloy) with strips provided, in some cases, to provide the additive materials or transition metals (e.g., strips of tungsten wrapped around the LiNi alloy rod or element). The specific amount of lithium ions 234 provided in the target 230 may also be widely varied to practice the method 100 and will depend upon a number of factors such as the particular electrochromic or battery device being built with the thin film provided by the target and the like.

Referring again to FIG. 1, the method 100 continues at 140 with positioning a substrate for a thin film and the target(s) of step 130 within a synthesis or deposition chamber (e.g., a PVD chamber or the like). For example, if the device is a battery device, the substrate may include one of the battery electrodes positioned on a substrate platform or substrate rack/holder. The target typically would be positioned within or adjacent a deposition mechanism (e.g., devices to cause radio frequency (RF) sputtering or the like from the target). At 150, the method 100 includes establishing the deposition conditions within the chamber such as by establishing a particular pressure (e.g., vacuum) and temperature and by injecting or providing a particular reactive environment (e.g., add gas or gases such as argon, oxygen, and the like). Additionally, the substrate may be heated or brought to a particular temperature to achieve a particular crystalline structure in the material deposited from the target.

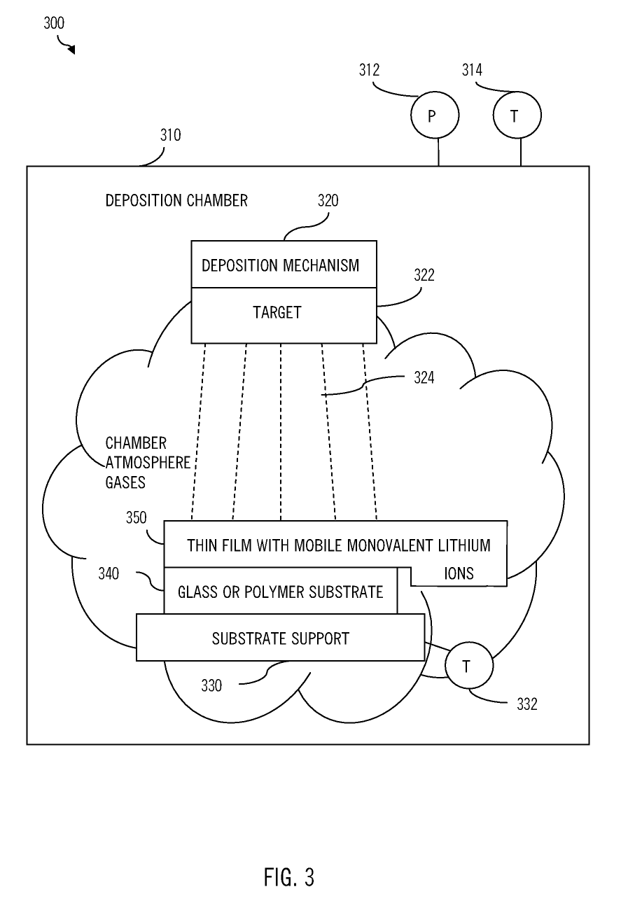

At step 160, the method 100 includes synthesizing lithiated transition metal oxide that forms as an electrochemical thin film upon the substrate (e.g., electrode materials are deposited on the exposed surface of the substrate). The deposited lithiated oxide or electrode typically will have a thickness of less than about 10 microns and, in some cases, the thin film formed will be less than 1 micron thick upon the substrate surface. FIG. 3 illustrates schematically a synthesis assembly 300 for forming lithiated transition metal oxide layers (e.g., for performing steps 140-160 of method 100). As shown, the assembly 300 includes a deposition or synthesis chamber 310 such as a PVD chamber that may be evacuated and/or have its pressure and atmosphere carefully controlled as shown with pressure gauge 312 and thermometer 314 (with pressure and temperature regulators and components not shown in this case but well understood by those in the arts). Further, supplemental gases 316 such as oxygen, hydrogen, nitrogen, or the like or inert gases like argon, xenon, or the like may be injected into the chamber 310 to create an environment conducive to depositing or synthesizing a thin film as described herein. A deposition mechanism 320 is provided within the chamber 310 such as a RF sputtering or other PVD deposition components. A target 322 (such as target 230 of FIG. 2) is manipulated by the mechanism 320 to release deposit materials 324 that are deposited upon one or more exposed surfaces of a substrate 340 as a thin film 350, e.g., a thin film of transition metal oxide with mobile monovalent lithium ions. The substrate 340 may be positioned and/or retained upon a substrate support 330, and this support or rack 330 may include one or more heaters or other devices to control or set the temperature of the substrate 340 as shown with thermometer/gauge 332. Once the film 350 is formed, the substrate 340 with the film 350 may be removed from the chamber 310 and used in further fabrication steps.

Specifically, the method 100 continues at 170 with performing additional deposition and/or fabrication steps to form a thin film electrochemical device such as an EC device or a thin film battery device. The method 100 may continue with fabrication of additional thin films of the same makeup at 130 or 140 (as shown) or with a new design and/or material makeup as shown such as at step 110 or the like. Alternatively, the method 100 may end at 190.

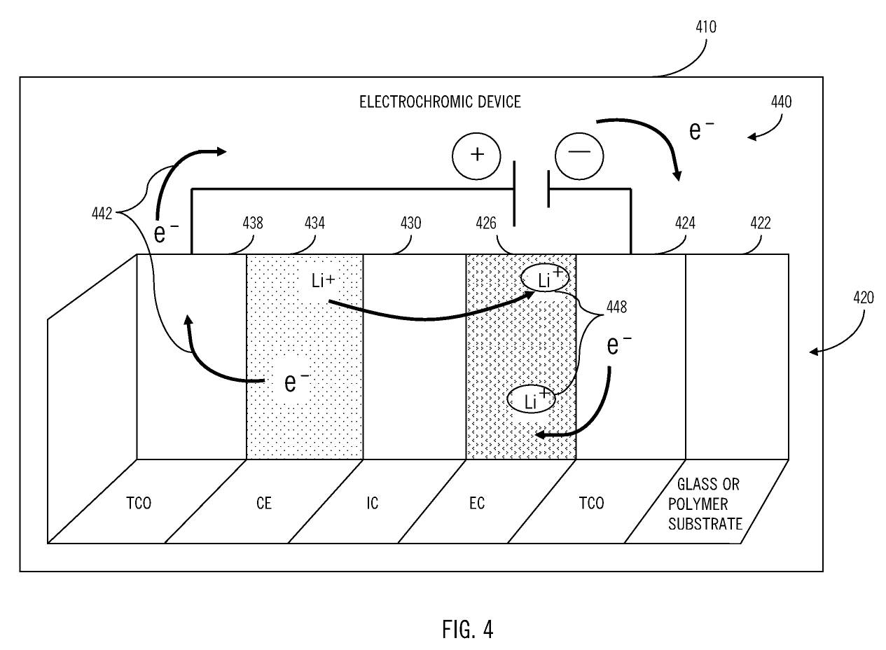

As discussed, method 100 and variations may be used to fabricate electrochemical devices with lithiated thin films or EC electrodes that are formed in a single deposition step. FIG. 4 illustrates schematically a representative electrochemical device using such thin films. As shown, an EC device 410 may be formed using the methods described herein to produce a stack of solid state films 420 that may then be connected to drive circuitry 440 to provide desired functionality such as changing optic properties of the thin film layers or electrodes formed according to method 100. The EC device stack 420 includes a glass substrate 422 but other substantially transparent materials such as plastics, ceramics, and the like may be used for smart window and other applications in which transparency or high light transmissivity is desired. A first transparent conductor 424 is provided on the glass substrate 422 such as a layer of deposited indium-doped tin oxide (ITO) or another transparent conducting oxide (TCO). An EC electrode 426 is provided next in the stack 420 and may be a lithiated transition metal oxide thin film (e.g., have mobile lithium ions 448) formed according to the single-step lithiation deposition techniques described herein such as with an ITO-coated glass as the deposition substrate or surface. An electrolyte or ion conductor 430 is positioned adjacent the EC electrode 426 and may be deposited upon the EC electrode 426 in a separate step.

A second electrode 434 may be formed upon the ion conductor 430 such as by using the one-step lithiation method described above to provide a lithiated transition metal oxide thin film with complementary ion transfer properties to the EC electrode 426 (e.g., to act as a counter electrode in the EC device 410 by also providing mobile lithium ions 444). Next, a second transparent conductor 438 may be provided adjacent or over the counter electrode 434. The drive circuitry 440 is connected to the two transparent conductors 424, 438 to selectively and in a switching manner control the flow of electrons 442 to modify the optical properties of the device 410, e.g., by causing the mobile lithium ions in the counter or EC/working electrode 434 or 426 to be conducted through the electrolyte 430 with the device 410 being transparent when lithium 448 moves from the EC electrode 426 to the counter electrode 434 and being dark or less light transmissive when lithium 444 moves from the counter electrode 434 to the EC electrode 426. In cases where it is desirable to produce a thin film battery device in place of the EC device 410, the glass substrate 422 may be eliminated (and replaced with a nontransparent substrate) and the two transparent conductors 424, 438 may be replaced with conductors having enhanced conductance properties (e.g., a layer of a nontransparent metal).

With the general description provided, it may be useful to provide examples of specific source materials and devices that may be formed according to these thin film synthesis techniques. In one embodiment, sputtering was utilized as the PVD method with a LiWO₃ target. The lithiated transition metal oxide material produced from this target was used to form in one deposition step a thin film of LiₓWO₃ (with “x” being chosen to obtain desired mobile lithium ion levels with “mobile” lithium here and throughout generally meaning that a substantial portion of the lithium will move in the presence of an electrical field typically at room temperature). Another useful example is the making or depositing of a Li_{y}(Ni—W—O) anodic EC layer by RF sputtering of a Li—Ni—W—O composite target (again with “y” being selected to obtain a desired amount of mobile lithium ions to achieve desired EC device or thin film battery characteristics). In another embodiment, the structure of the EC thin film device took the following stack form: substrate/TCO/LiₓWO₃/Li-ion conductor/Li_{y}(Ni—W—O)/TCO. The total amount of lithium (i.e., x+y) in the device can be easily and accurately controlled to optimize or set the EC optical contrast as well as other device operation characteristics such as bleached state transmittance of the device (or charge capacity/ion mobility as in the case of thin film batteries). By using the one-step deposition process to provide lithiated thin films, a solid state EC thin film structure can be deposited by employing a significantly less complex and more cost effective synthesis process.

In addition to the advantage of removing the cumbersome extra lithiation step, the method described here has another important and beneficial ramification. Thin films deposited from a lithiated compound (e.g., a LixWO3, Li—Ni—W—O composite, and so on) may exhibit advantageous nanocrystalline characteristics when deposited upon a heated or, in some cases, unheated or room temperature substrate. Thin films with these nanocrystalline physio-chemical properties have been found to show a superior cycling stability than those with conventional amorphous characteristics.

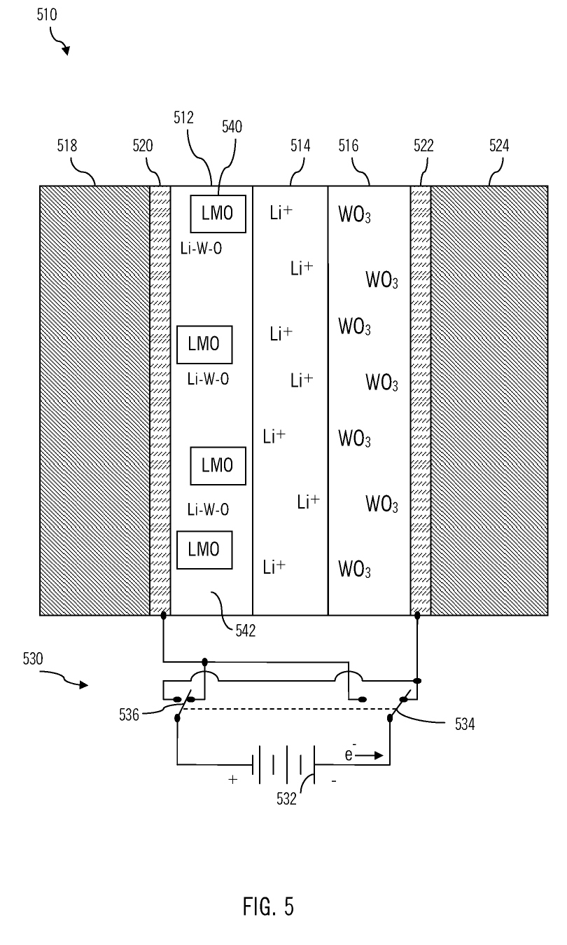

Another example EC device is a lithium ion electrochromic cell 510 as shown diagrammatically in FIG. 5. The cell 510 is useful to illustrate an example implementation of a lithium ion electrochromic cell formed with particular target materials to form the counter and EC electrodes (or positive and negative electrodes). As shown, the cell 510 has a positive electrode 512 including lithium nickel tungsten oxide and, in some cases, this is formed as nanocomposite material. A lithium ion electrolyte 514 is positioned between a positive electrode 512 on a substrate 518 and a negative electrode 516 on a substrate 524. Contact layers 520, 522, for example, a transparent conducting oxide (TCO), can be provided for electrical connection of the electrochromic cell 510 to an external circuit having a power source 532, such as the external circuit 530 illustrated schematically in FIG. 5 as an example.

In the example electrochromic device 510, the negative electrode 516 (also sometimes called the active or EC electrode or cathode) is shown as made up of a normally reduced tungsten oxide (WO₃) (sometimes alternatively called tungstic oxide or tungsten trioxide) material, although it could be any of a number of normally reduced materials typically used for negative electrodes in chemochromic devices. The positive electrode 512 (also sometimes called the counter electrode or anode) may in some embodiments be a nanocomposite material (that may be polycrystalline) such as at least partially lithiated, metal oxide (LMO) nanoparticles 540 surrounded by a lithium-based, solid-state superionic conductor 542 including lithium-tungsten-oxide (Li—W—O). The LMO and Li—W—O designations are general notations for the illustration in FIG. 5. These materials that make up the nanocomposite material of the positive electrode 512 will be described in more detail below. Nanoparticle here means less than 0.1 micrometer. This nanocomposite material for the positive electrode 512 can be deposited, for example, by sputtering from a sintered ceramic target including lithium oxide (Li₂O), a metal oxide (MO) to provide an active metal, and tungsten oxide (WO₃), where M can be Ni, Mg, Co, or Fe. The sputtering may produce nanoparticles of the lithiated metal oxide, for example lithiated nickel oxide (LiₓNi₁₋ₓO), which are characterized by crystallite sizes in the nanometer range, i.e., less than 0.1 micrometer, and preferably, but not necessarily, about 5 to 35 nm. The LiₓNi₁₋ₓO crystallites in this nanocomposite material, i.e., in the lithium nickel tungsten oxide (sometimes abbreviated as “LNWO”) are much smaller than the crystallites in previously used positive electrode materials such as LiNiO₂ that may not provide desired amounts of ion mobility.

The tungsten oxide is amorphous and can be composed of at least one of lithium and lithium tungsten oxides, for example Li₂O, LiWO₃, and Li₂WO₄, and is usually a mixture including more than one of these materials. The partially lithiated metal oxide (LMO), for example, LiₓN₁₋ₓO (where 0≦x≦0.5), may be a crystalline structured nanoparticle because the tungsten oxide prevents the nickel oxide or other metal oxide used from forming large, crystalline structures. The lithiated metal oxide, e.g., the partially lithiated nickel oxide, nanoparticles 540 have large surface area/volume ratios, e.g., in a range of 0.12 nm⁻¹ to 1 nm⁻¹, and they are in intimate contact with the surrounding solid-state lithium ion superionic conductor 542, which basically fills the pores between the lithiated metal oxide nanoparticles 540, thereby maximizing the usage and accessibility of the total surface of the metal oxide nanoparticles. The terms partially lithiated and lithiated are used interchangeably when referring to the partially lithiated and lithiated metal oxides, because the extent of the lithiation of the metal oxides in the nanocomposite material (LMO) can vary and may even include some amount of metal oxide crystallites or nanoparticles that are not lithiated, as indicated above in the example LᵢₓNi₁₋ₓO (where 0≦x≦0.5). The electrolyte layer 514 can be LiPON or any other suitable electrolyte that provides a supply of lithium ions (Li+) for transport back and forth between the negative electrode 516 and the positive electrode 512.

As mentioned above, the negative electrode 516 is a normally oxidized material, for example, tungsten oxide (WO₃), which is bleached or clear in its normal oxidized state, but which darkens or colors to a dark blue upon insertion of lithium ions (Li⁺) from the electrolyte and reduction to a higher energy state in the form of LiₙWO₃ upon application of a voltage to a circuit 530 that causes a flow of electrons into the negative electrode 16 to accommodate overall charge neutrality according to the general formula:

WO₃+ne⁻+nLi⁺→Li_{y}WO₃

where y can be a number between 0 and 3.

This reaction is reversible to transform the dark colored Li_{y}WO₃ back to transparent WO₃, which can occur automatically when an external circuit to accommodate flow of electrons from the negative electrode back to the positive electrode or which can be accelerated by reversing the voltage polarity of the external circuit 530, for example, by switching the switches 534, 536 shown schematically in FIG. 5. The reverse reaction from the dark state to the transparent state is:

Li_{y}WO₃→WO₃+nLi⁺+ne⁻

where y can be a number between 0 and 3.

The lithium nickel tungsten oxide nanocomposite material has been prepared, for example, by RF magnetron sputtering from a sintered ceramic target including lithium oxide, nickel oxide, and tungsten oxide, as will be described in more detail below. The tungsten oxide is believed to prevent the nickel oxide from forming large crystalline structures. However, there is little, if any, nickel-tungsten oxide (NiWO) in the lithium nickel tungsten oxide nanocomposite material, and the lithium ion superionic conductor 542 including lithium-tungsten oxide is a superior conductor of lithium ions (Li⁺) from the electrolyte 514 to the nickel oxide crystallites 540. Nickel oxide (NiO) is a dense structure, thus typically slow to oxidize in larger crystalline form, so the nanocrystalline, nearly X-ray amorphous, partially lithium-substituted nickel oxide 540 described herein is more accessible to lithium ions, but the oxidation reaction of Ni²⁺ (clear or bleached to Ni³⁺ (darkened) in the positive electrode 512 is enhanced even further by the lithium-tungsten oxide superionic conductor matrix 542 in the lithium nickel tungsten oxide nanocomposite material (LNWO), which in a functional sense, becomes an extension of the electrolyte 514.

Since the electrochromic transition from clear or bleached state to a darkened state in the positive electrode 512 is provided primarily by the oxidation of the nickel oxide in the positive electrode 512, albeit enhanced by the nanocrystallite structure of the lithiated nickel oxide and by the lithium ion conductor matrix 542 of lithium-tungsten oxide as described above, the oxidation reaction is typical for nickel oxide counter electrodes in lithium ion electrochromic devices, i.e.,

LiₙNiO→NiO+nLi⁺+ne⁻

where n can be nearly any number subject to limitations such as steric hinderance. To revert back from dark to clear, the reduction reaction is:

NiO+ne⁻+nLi⁻→LiₙNiO

where n again can be nearly any number. In the reverse (reduction) reaction, the Li⁺ and the compensating e⁻ change any Ni³⁺ (dark) in the film into N²⁺ (clear). Note that the crystallites in our film start in some intermediate colored state, since they are partially lithiated.

As mentioned briefly above, the lithium nickel tungsten oxide nanocomposite material (LNWO) for the positive electrode 512 can be provided by RF sputtering of a sintered ceramic target of lithium oxide, nickel oxide, and tungsten oxide onto a substrate (or onto a contact conductor layer 520 on a substrate 518), but other deposition techniques, such as pulsed laser deposition, DC sputtering of ceramic targets, and DC/RF reactive sputtering of metallic alloy targets, can also be used.

For example, target materials (such as materials 130 of FIG. 1) including lithium oxide, nickel oxide, and tungsten oxide have been prepared by pressing a mixture of powdered Li₂CO₃, NiO, and WO₃ in a hydraulic press to produce pellets of the mixture. The resulting pellets were then heated in an oven to at least 700° C. to volatize and remove the carbon from the lithium carbonate. Subsequently, the pellets without the carbon were ground back to powder form, repressed, and then reheated to form a durable target material for use in growing thin films of the lithium nickel tungsten oxide nanocomposite material (sometimes abbreviated as “LNWO”) by pulsed laser deposition or sputtering. Higher sintering temperatures can be chosen in order to yield a stronger, more durable target. However, due to the relative volatility of the lithium, the resulting targets could be lithium reduced compared to the films described below. The thin films that have been grown using RF magnetron sputtering of such lithium nickel tungsten oxide nanocomposite material with a stoichiometric ratio of Li:Ni:W=1.2:1.0:0.1 in the target have shown strong anodic electrochromic activity as well as high charge capacity for battery applications, as will be described in more detail below. However, the optimal ratio of Li:Ni:W can be varied from this ratio to modify desired performance characteristics. In general, the LiₓNi₁₋ₓO nanoparticles can comprise in the range of 25 to 99 percent of the LNWO while the lithium tungsten oxide matrix comprises one to 75 percent of the LNWO.

For several examples described below, a target was made from a mixture 14.0271 grams of Li₂CO₃, 23.6328 grams of NiO, and 7.3353 grams of WO₃ for a starting stoichiometry ratio of (Li₂CO₃)_{0.6}(NiO)_{1.0}(WO₃)_{0.1}. This mixture was pressed and sintered at 700° C. for eight hours. After the carbon was volatized and removed, the remaining material was ground down and re-pressed into pellets and reheated at 700° C. for eight hours two times to form a sputtering target with a nominal ratio of Li:Ni:W=1.2:1.0:0.1.

### EXAMPLE I

A LNWO layer about 110 nm thick was grown from the target material described above onto fluorine-doped tin oxide (FTO) glass substrates by RF sputtering in an atmosphere of pure argon.

### EXAMPLE II

A LNWO layer about 80 nm thick was grown from the target material described above onto FTO glass substrates by RF sputtering in an atmosphere of one-third oxygen and two-thirds argon.

### EXAMPLE III

A LNWO layer about 100 nm thick was grown from the target material described above onto FTO glass substrates by RF sputtering in an atmosphere of two-thirds oxygen and one-third argon.

### EXAMPLE IV

A LNWO layer about 110 nm thick was grown from the target material described above onto FTO glass substrates by RF sputtering in an atmosphere of pure oxygen.

### EXAMPLE V

A LNWO layer about 115 nm thick was grown from the target material described above onto FTO glass substrates by RF sputtering in an atmosphere of one-half oxygen and one-half argon.

The LNWO materials from the Examples I-IV bleached quickly from an initial dark color to a very clear bleached state, but they could not be re-colored. Their poor performance is probably attributable to incomplete burn-in of the target. However, the LNWO material from Example V performed very well. From an initial dark color, it bleached and darkened well with excellent repeatability. It also had a total charge per cycle of 15 μAh/cm².

On LNWO films with varying compositions, thicknesses, and growth parameters, inductively-coupled plasma mass spectrometry has shown the nickel-tungsten ratio of the films to be roughly equal to that of the targets from which they were grown. Also, X-ray diffraction and transmission election microscopy experiments have shown the films to be nanocrystalline, as will be related in the following examples.

### EXAMPLE VI

A LNWO layer about 300 nm thick was grown from a target material comprised of lithium oxide, nickel oxide, and tungsten oxide with a ratio of Li:Ni:W=1.5:1:0.25. The LNWO was deposited on a stainless steel substrate by RF sputtering in an atmosphere of half O₂ and half Ar.

A diffraction experiment was performed using a LNWO film with a ratio of Li:Ni:W=1.2:1:0.1 that was grown on a glass substrate. The shift in peaks in the as-deposited films is a combination of lithium substitution and nickel ion size. The Ni(II) and Ni(III) have different effective radii, so when the film bleaches or darkens there is a peak shift. These results appear to show or prove that the NiO particles are deposited in a partially lithiated state, i.e., LiₓNi₁₋ₓO as described above. Transmission electron microscope (TEM) inspection of another LNWO sample showed that the nanostructures and nanocrystals are less than one micrometer in size in the deposited film. For that LNWO sample, a 250 nm thick film of LNWO was grown on a glass substrate, which was pre-coated with fluorine-doped tin oxide. The LiₓNi₁₋ₓO grains were clearly visible under the TEM microscope as was the lattice structure in the grains. Using the microscope electron beam, it was possible to get electron diffraction patterns from individual grains. For this film, the patterns confirm the results from the X-ray diffraction experiment described above. The nanocrystalline nature of the film was also evident in testing due to a finding that a lithiated thin film had a broad, flat voltage versus charge trace that would be characteristic of more fully crystalline film, whereas a uniform, straight decrease would be characteristic of an amorphous film.

The results described above clearly show that the LNWO films are a nanostructured composite of LiₓNi₁₋ₓO and lithium tungsten oxide compounds. As explained above, the very small lithiated NiO crystallite nanostructures 540 in combination with the lithium ion superionic conductor matrix 542 result in unexpectedly large enhancements in electrochromic activity of the lithium nickel tungsten oxide nanocomposite material over, for example, NiO alone and even over lithium nickel oxide (LiNiO₂). For example, a comparison of the transmittance versus wavelength of a sample LNWO nanocomposite material thin film 110 nm thick (ratio Li:Ni:W=1.2:1:0.1) when bleached and dark with a LiNiO₂ thin film, which is also approximately 70 nm thick, when bleached and dark shows that the transmittance difference between the bleached and dark for the LNWO nanocomposite material is much larger than for the LiNiO₂ in the visible wavelength range of about 400 to 700 nm (e.g., about twice as large in the middle of the visible range). Thus, the greatest electrochromic change in the LNWO happens to be at about the peak of the photopic eye response of humans (an ideal optical performance characteristic). It is interesting to note that even though the LNWO film is thicker than the LiNiO₂ film, the LNWO film is more transparent in the bleached state.

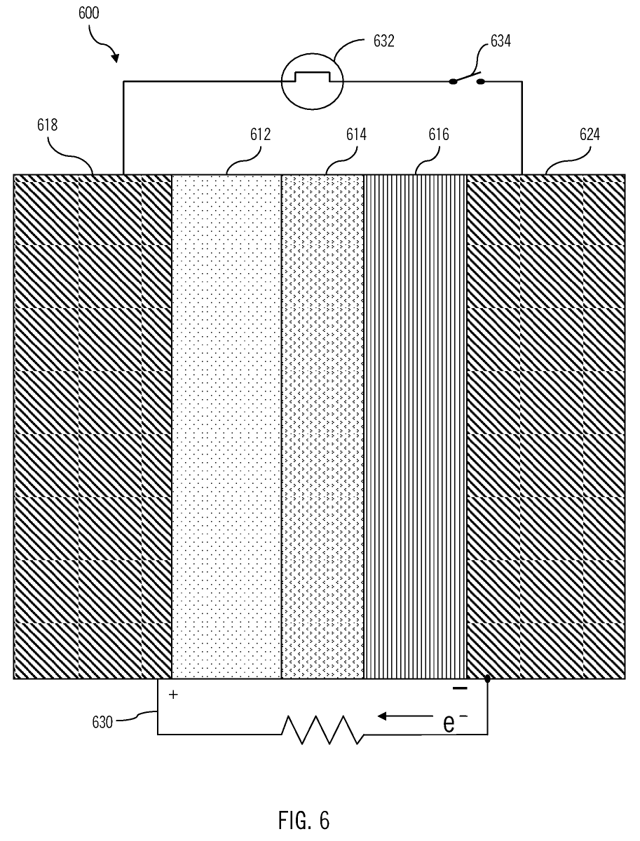

As also mentioned above, the charge capacity of the lithium nickel tungsten oxide nanocomposite material is very high, so it can function as the positive electrode (cathode) 612 of a lithium ion battery cell 600, as illustrated diagrammatically in FIG. 6. Since none of the components of a battery have to be transparent, the lithium nickel tungsten oxide nanocomposite material (LNWO) of the positive electrode 612 can be deposited directly on a metal or other conductive substrate or layer 618, if desired. The negative electrode (anode) 616 does not have to be electrochromic, so any common negative electrode material used for lithium ion battery cells can be used such as lithium metal, graphite, silicon or tin alloys with other options including metal oxides, such as WO₃, as listed above. The example cell 600 in FIG. 6 is illustrated for example with lithium metal (Li) for the negative electrode 616, and it can be deposited on any suitable conductive metal or other conductive substrate or contact 624. Likewise, the electrolyte 614 can be any of the materials mentioned above or others that provide lithium ions (Li⁺) for intercalation with the positive and negative electrode materials.

In operation, during discharge, the Li metal is inherently unstable, thus at a higher energy state than oxidized lithium ions (Li⁺). Therefore, the lithium metal oxidizes and gives up electrons, which flow through the external circuit 630, including the load 631, to the positive electrode 612, which includes the LNWO as described above. The reaction at the negative electrode 616 is:

nLi→nLi⁺+ne⁻

where n can be any number, and it is reversible upon application of a higher voltage source 632 in the external circuit to drive reducing electrons back into the Li negative electrode 616 to thereby reduce Li⁺ to the higher energy state of lithium metal. Such recharging can be implemented, for example, by closing a switch 634.

In the positive electrode 612 during discharge of the battery cell 600, the LNWO functions substantially as described above for the electrochromic cell 510. LNWO may have charge capacity enhanced as high as 250 μAh/gram, as shown in the following Example VII, which compares very favorably to the approximately 120 μAh/gram capacity of typical LiCoO₂ positive electrodes, which are current state-of-the-art in lithium ion batteries.

### EXAMPLE VII

In one film produced according to the processes described herein, the Li:Ni:W ratio was 1.2:1:0.1, and the film thickness was 115 nm. The total capacity for a 1 cm² film was found to be about 1.45 μAh/cm². Given that the film density was about 5.0 g/cm³, the capacity on full discharge is approximately 250 μAh/gram. Depending on specific necessary voltages and cycling needs of a given battery application, the actual charge capacity might be higher or lower than this number.

While a number of exemplary aspects and embodiments have been discussed above, those of skill in the art will recognize certain modifications, permutations, additions, and sub-combinations thereof. It is therefore intended that the following appended claims and claims hereafter introduced are interpreted to include modifications, permutations, additions, and sub-combinations to the exemplary aspects and embodiments discussed above as are within their true spirit and scope. The formation of thin films for use as the EC working electrode and the counter electrode for EC devices and thin film batteries has been stressed in this description, but it should be understood that the one-step method of deposition using a lithiated EC source material or target may be used for any electrode or ionic conductors. The transition metal oxide material included in the synthesis source or deposition target may be any of a number of metal oxides with the particular metal chosen depending upon the thin film's or device's functionality. For example, the metal oxide may be chosen to provide a desired color change efficiency (e.g., be tungsten oxide with or without added active metals such as nickel) when the device is an EC device and be chosen to provide a more efficient electrical conductor (e.g., an oxide of titanium, cobalt, iron, manganese, nickel, and the like) to provide enhanced charge capacity when the device is a thin film battery. Further, deposition is intended to be construed broadly to include PVD techniques and other techniques such as chemical vapor deposition (CVD) and the like.

1. A method of synthesizing a thin film electrode, comprising:
within a deposition chamber, providing a source material comprising a transition metal oxide and lithium;
positioning an electrically conductive substrate with a surface exposed to an interior of the deposition chamber; and
depositing a thin film of the transition metal oxide and the lithium on the substrate surface by performing deposition within the deposition chamber using the source material, wherein the lithium in the deposited thin film is in unbound ionic form and is mobile.

2. The method of claim 1, wherein the lithium in the source material is in ionic form.

3. The method of claim 2, wherein the ionic lithium in the deposited thin film has mobility and concentration values allowing the deposited thin film to function as an electrode in an electrochromic device or in a thin film battery.

4. The method of claim 1, wherein the transition metal oxide comprises tungsten.

5. The method of claim 4, wherein the source material further comprises nickel and the deposited thin film comprises at least a portion of the nickel from the source material.

6. The method of claim 1, further comprising prior to the depositing step forming the source material into a ceramic target and wherein the deposition comprises physical vapor deposition including sputtering with the ceramic target.

7. The method of claim 1, wherein the substrate comprises a transparent conducting oxide and the thin film forms an electrochromic electrode.

8. A method of fabricating an electrochromic device, comprising:
providing a substrate including a transparent conductor layer; and
performing physical vapor deposition upon the transparent conductor layer using a target comprising lithiated electrochromic material.

9. The method of claim 8, wherein the lithiated electrochromic material comprises a transition metal oxide and the performing of the physical vapor deposition generates a lithiated thin film of the transition metal oxide.

10. The method of claim 9, wherein the transition metal oxide comprises tungsten.

11. The method of claim 8, further comprising forming the target from a source material for lithium in ionic form and a transition metal oxide material.

12. The method of claim 11, wherein the forming further comprises processing the lithium source material to produce the ionic form lithium.

13. The method of claim 8, further comprising providing an ion conductor on an electrochromic electrode formed on the transparent conductor during the physical vapor deposition and further comprising after the providing of the ion conductor, performing an additional physical vapor deposition using an additional target comprising a lithiated electrochromic material to produce a thin film counter electrode on the ion conductor.

14. A method of forming a thin film electrode, comprising:
providing a source material comprising a transition metal and a quantity of material comprising a substantial fraction that is lithium in ionic form; and
depositing a thin film comprising the source material on a substrate.

15. The method of claim 14, wherein the depositing comprises physical vapor deposition and wherein the transition metal is provided in the source material as a transition metal oxide and wherein the lithium in the thin film is substantially mobile.

16. The method of claim 15, wherein the thin film is an electrochromic electrode.

17. The method of claim 16, wherein the transition metal oxide comprises tungsten oxide and the substrate comprises a transparent conductor.

18. The method of claim 14, wherein the ionic lithium in the deposited thin film is unbound and has a mobility and concentration whereby the deposited thin film functions as an electrode in a thin film battery.

19. The method of claim 14, wherein the source material further comprises an active metal comprising nickel.

20. The method of claim 14, wherein the source material is LiₓWO₃ or Li—Ni—W—O composite.
